(19) United States
(12) Patent Application Publication
(10) Pub. No.: US 2006/0219386 A1
(43) Pub. Date: Oct. 5, 2006

(54) Heat dissipating assembly with composite heat dissipating structure

(75) Inventors: Alex Hsia, Taoyuan Hsien (TW); Chin Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/187,942

(22) Filed: Jul. 25, 2005

(30) Foreign Application Priority Data
Apr. 1, 2005 (TW) 094110425

(51) Int. Cl. H05K 7/20

(52) U.S. Cl. 165/80.3; 361/697; 361/704; 257/722; 165/121; 165/185

(57) ABSTRACT

A heat dissipating assembly includes a fan and a composite heat dissipating structure. The composite heat dissipating structure includes a first heat sink and a second heat sink disposed adjacent to the first heat sink. The first and the second heat sinks include a plurality of first fins and a plurality of second fins respectively. The arrangement of the first fins is different from that of the second fins so as to flexibly regulate heat dissipation. Also, the fan dissipates heat accumulated in the composite heat dissipating structure and facilitates heat transmitted by the composite heat dissipating structure to dissipate more efficiently.

### BACKGROUND OF THE INVENTION

1. Field of Invention

The present invention relates to a heat dissipating assembly, and in particular to a heat dissipating assembly with a composite heat dissipating structure.

2. Related Art

Due to rapid development of technology, the amount of transistors within an unit area of an electronic device is more and more increasing, which causes much heat dissipated from the electronic device during operation. In order to maintain the electronic device within operation temperature, a fan and a heat sink are conventionally applied to perform heat dissipation.

As shown in FIG. 4, a conventional heat dissipating assembly 4 includes a heat sink 41, a fan 42, a locking frame 43 and a support 44. The heat sink 41 is disposed on the support 44 and is sandwiched between the locking frame 43 and the support 44. The fan 42 is locked on the locking frame 43. The fan 42 locates on the heat sink 41 for heat guiding and dissipating.

The heat sink 41 has a plurality of fins for enlarging a dissipating area, but it is considering that the distribution, shape and arrangement of the fins have great influences to heat dissipating effect. In spite of the more fins enlarging the dissipating area, however, too many fins cause less stream flowing through the fins of the heat sink 41. Therefore, too many fins decrease heat guiding of the fan 42 and weaken heat dissipating effect under than expectation.

Conventionally, the heat sink 41 is made by welding several copper sheets thereonto, and which leads to many operations and high-cost. Another well-known manufacturing method is extruded aluminum molding with advantages of easy-operation and low-cost. However, the extruded aluminum molding is limited by fin distribution, shape and arrangement on a single heat sink. As a result, the heat dissipating structure made by the extruded aluminum molding could not be flexible to meet practical design.

It is therefore an important subject of the present invention to provide a heat dissipating assembly and a composite heat dissipating structure to solve above-mentioned problems.

### SUMMARY OF THE INVENTION

In view of the foregoing, the present invention is- to provide a heat dissipating assembly with a composite heat dissipating structure for an effective heat guiding and dissipation.

To achieve the above, a composite heat dissipating structure according to the present invention includes a first heat sink and a second heat sink. The first heat sink has a plurality of first fins, and the second heat sink has a plurality of second fins. The first and the second heat sinks are disposed adjacently and the arrangement of the first and the second fins is different. The amount of the first fins is different from that of the second fins.

The first heat sink has a first heat conductive part to which the first fins are connected, and the second heat sink has a second heat conductive part to which the second fins are connected. The first and the second heat conductive parts are connected so that the first and the second heat sinks are disposed adjacently.

Alternatively, the first and the second heat conductive parts have a through hole respectively and the through holes are connected for accommodating a corresponding heat conducting base, so that the first and the second heat sinks are disposed adjacently. The heat conducting base is a solid metal or a thermal pipe.

Further, a heat dissipating assembly according to the present invention includes a composite heat dissipating structure and a fan. The composite heat dissipating structure includes a first heat sink and a second heat sink. The first heat sink has a plurality of first fins, and the second heat sink has a plurality of second fins. The first and the second heat sinks are disposed adjacently and the arrangement of the first and the second fins is different. The fan is applied to the composite heat dissipating structure for dissipating heat accumulated in the composite heat dissipating structure and facilitating heat transmitted by the composite heat dissipating structure to dissipate more efficiently.

### BRIEF DESCRIPTION OF THE DRAWINGS

The present invention will become more fully understood from the detailed description given herein below illustration only, and thus is not limitative of the present invention, and wherein:

FIG. 1A is a three-dimensional decomposed view showing a preferred embodiment of a composite heat dissipating structure according to the present invention;

FIG. 1B is a side view of FIG. 1A after mounting;

FIG. 2 is a three-dimensional decomposed view showing another preferred embodiment of a composite heat dissipating structure according to the present invention;

FIG. 3A is a three-dimensional decomposed view showing a preferred embodiment of a heat dissipating assembly according to the present invention;

FIG. 3B is a side view of FIG. 3A after mounting; and

FIG. 4 is a three-dimensional view showing a conventional heat dissipating assembly.

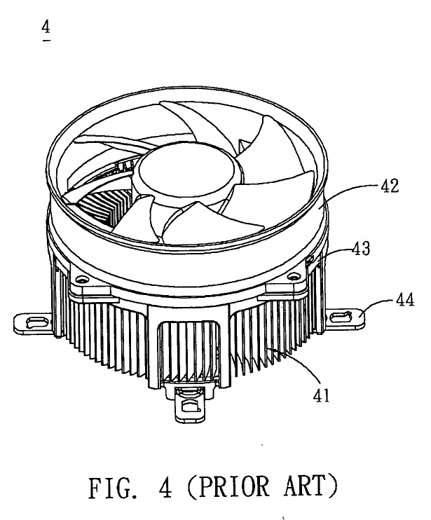

### DETAILED DESCRIPTION OF THE INVENTION

The present invention will be apparent from the following detailed description, which proceeds with reference to the accompanying drawings, wherein the same references relate to the same elements.

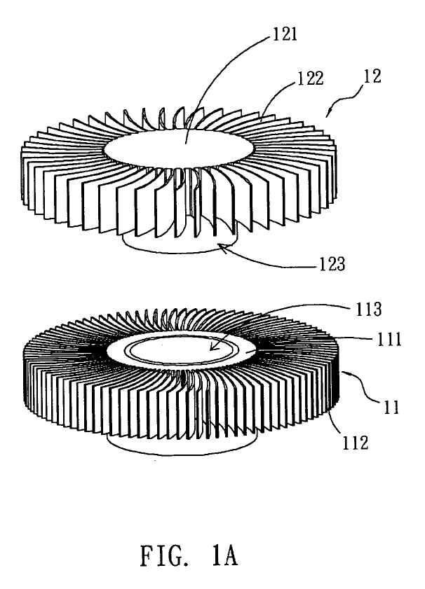

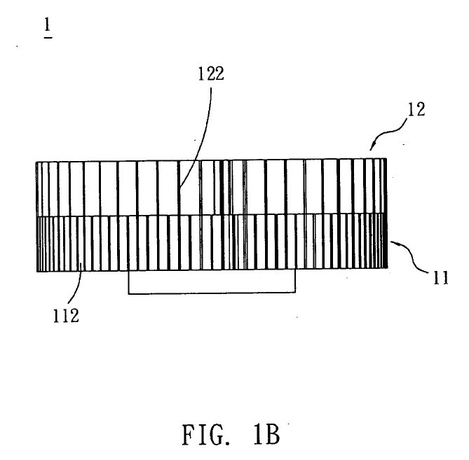

As shown in FIGS. 1A and 1B, a preferred embodiment of a composite heat dissipating structure 1 according to the present invention includes a first heat sink 11 and a second heat sink 12. The first heat sink 11 has a first heat conductive part 111 and a plurality of first fins 112 connected to the first heat conductive part 111. The second heat sink 12 has a second heat conductive part 121 and a plurality of second fins 122 connected to the second heat conductive part 121. The first heat sink 11 and the second heat sink 12 are disposed adjacently and the arrangement of the first fins 112 and the second fins 122 is different. In this embodiment, the first fins 112 and the second fins 122 are respectively arranged in radial distribution around the first heat conductive part 111 and the second heat conductive part 121. Because the amount of the second fins 122 is less than that of the first fins 112, the distribution density of the second fins 122 is lower than that of the first fins 112.

The first heat sink 11 and the second heat sink 12 of the composite heat dissipating structure 1 are disposed adjacently by the connection of the first heat conductive part 111 and the second heat conductive part 121, and then the first heat sink 11 and the second heat sink 12 are integrated to form a single structure. As shown in FIG. 1A, the first heat conductive part 111 has an indentation 113, and the second heat conductive part 121 has a corresponding protrusion 123 to be coupled to the indentation 113 of the first heat conductive part 111, so that the first heat sink 11 and the second heat sink 12 are disposed adjacently.

In this embodiment, the connection between the indentation 113 of the first heat conductive part 111 and the protrusion 123 of the second heat conductive part 121 may be welding,, embedding, locking, adhesion or any other connection ways. Further, the first heat conductive part 111 and the second heat conductive part 121 may be embedded and/or locked by thermal mounting. By the application of thermal expansion, the indentation 113 and the protrusion 123 are able to be connected more tightly. Additionally, a soldering paste, grease or material for thermal interface may be disposed between the indentation 113 and the protrusion 123 in order to enhance the connection strength between the first heat sink 11 and the second heat sink 12 and to achieve a smooth interface for improving heat conduction effect.

In this embodiment, the first fins 112 and the second fins 122 are respectively arranged in radial distribution around the first heat conductive part 111 and the second heat conductive part 121. Alternatively, the first fins 112 and the second fins 122 can be designed in different shapes or be arranged in other distributions, such as horizontal distribution, vertical distribution, inclined distribution, radial distribution or any other distribution ways.

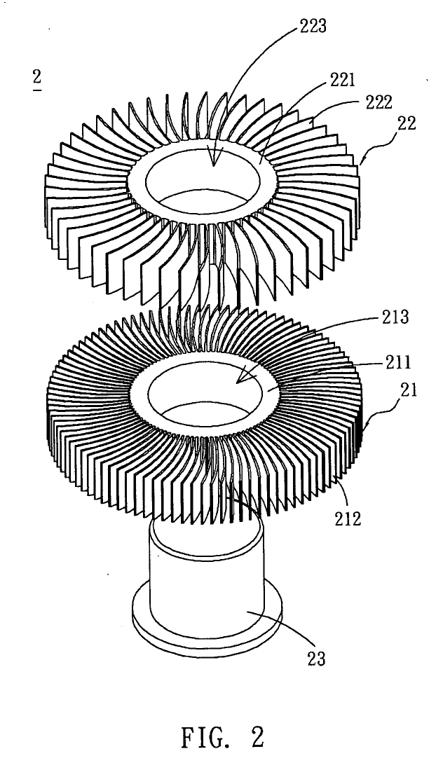

As shown in FIG. 2, another preferred embodiment of a composite heat dissipating structure 2 according to the present invention includes a first heat sink 21, a second heat sink 22 and a heat conducting base 23. The first heat sink 21 has a first heat conductive part 211 and a plurality of first fins 212 connected to the first heat conductive part 211. The second heat sink 22 has a second heat conductive part 221 and a plurality of second fins 222 connected to the second heat conductive part 221.

The first heat conductive part 211 has a first through hole 213 and the second heat conductive part 221 has a second through hole 223. When the first heat sink 21 and the second heat sink 22 are arranged adjacently, the first through hole 213 and the second through hole 223 are connected for allowing the corresponding heat conducting base 23 to pass therethrough and accommodating the corresponding heat conducting base 23, so that the first heat sink 21 and the second heat sink 22 are disposed adjacently. The heat conducting base 23 may be a solid metal or a thermal pipe. The connections between the first heat sink 21 and the heat conducting base 23 and between the second heat sink 22 and the heat conducting base 23 may be welding, embedding, locking, adhesion or any other connection ways. Further, the first heat sink 21, the second heat sink 22 and the heat conducting base 23 may be embedded and/or locked by thermal mounting. By the application of thermal expansion, the first heat sink 21, the second heat sink 22 and the heat conducting base 23 are able to be connected tightly. Additionally, a soldering paste, grease or material for thermal interface may be disposed between the heat conducting base 23 and the first heat sink 21 and between the heat conducting base 23 and the second heat sink 22 in order to enhance the connection strength between the first heat sink 21 and the second heat sink 22 and to achieve a smooth interface for improving heat conduction effect. The thermal pipe may be made of plastic, metal, alloy or nonmetal.

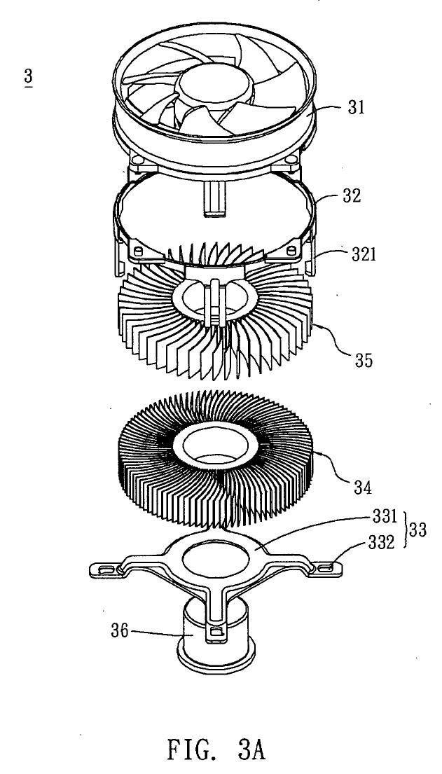

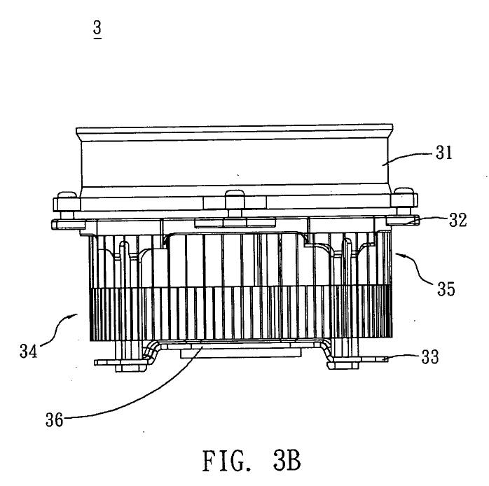

In addition, a fan may be applied to the composite heat dissipating structure 1 or 2 for dissipating heat accumulated in the composite heat dissipating structure and facilitating heat transmitted by the composite heat dissipating structure to dissipate more efficiently. As shown in FIGS. 3A and 3B, a preferred embodiment of a heat dissipating assembly 3 according to the present invention includes a fan 31, a locking frame 32, a support 33 and a composite heat dissipating structure. The composite heat dissipating structure includes a first heat sink 34 and a second heat sink 35.

The support 33 includes a central ring portion 331 for allowing a heat conducting base 36 to penetrate there through and to be positioned. The support 33 is for supporting the composite heat dissipating structure thereon and releasing the pressure acted onto a heat source which is under the support 33 and the composite heat dissipating structure. The heat conducting base 36 penetrates through the ring portion 331 of the support 33, the first heat sink 34 and the second heat sink 35 in order, so that the first heat sink 34 and the second heat sink 35 are connected to the heat conducting base 36 and collectively form a composite heat dissipating structure.

Four clasps 321 of the locking frame 32 separately lock with four locking holes 332 of the support 33, so that the locking frame 32 and the support 33 are connected, whereby the first heat sink 34 and the second heat sink 35 are sandwiched between the locking frame 32 and the support 33. The fan 31 is disposed on the locking frame 32 and locates above the first heat sink 34 and the second heat sink 35 in order to dissipate heat accumulated in the composite heat dissipating structure and facilitate heat transmitted by the composite heat dissipating structure to dissipate more efficiently.

The heat dissipating assembly 3 is applied to a heat source, such as an electrical device generating heat, for dissipating heat generated from the heat source. At first, the heat dissipating assembly 3 is disposed onto an electronic device and the heat conducting base 36 has direct contacts with the surface of the electronic device. Therefore, the heat generated from the electronic device is transmitted via the heat conducting base 36 to the first heat sink 34 and the second heat sink 35, and then dissipated by the fan 31.

According to the principle of heat transmittance, the closer to heat source may cause a better heat transmitting effect. That is, the heat sink with more fins should be disposed close to a heat source (electrical device generating heat). However, considering that more fins may cause disadvantage of poor stream guiding, another heat sink with less fins should be disposed apart from the heat source. As the result, by combining two different arrangement of fin distribution to form a composite heat dissipating structure, the present invention may achieve an optimal effect of heat dissipation. As shown in FIG. 3B, the first heat sink 34 is close to the heat source (not shown), the second heat sink 35 is apart from the heat source, and the amount of the first fins of the heat sink 34 is greater than that of the second heat sink 35. Because the first heat sink 34 has relatively greater fins, total heat dissipating area is relatively larger so that heat dissipation is increased effectively. Also, because the second heat sink 35 has relatively less fins, airflow of the fan 31 can easily enter the second heat sink 35, so that it facilitates heat guiding and dissipating to the environment.

In this embodiment, the fin distribution density of the second heat sink is lower than that of the first heat sink. Nevertheless, the fin distribution density of the first and the second heat sinks is adjustable in accordance with practical application. Also, the heat dissipating assembly according to the present invention may further include a third heat sink to provide more design flexibility.

In summary, due to the limitations of conventional fin distribution, shape and arrangement on a single heat sink made by an extruded aluminum molding, a composite heat dissipating structure and a heat dissipating assembly according to the present invention may overcome such limitations by integrating at lease two different heat sinks. Furthermore, considering the dissipating area under the same airflow of the fan, the present invention may facilitate heat guiding and dissipating within the heat sinks to achieve an effective heat dissipation and be flexible in accordance with practical application.

Although the present invention has been described with reference to specific embodiments, this description is not meant to be construed in a pivoting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A composite heat dissipating structure, comprising:
a first heat sink, having a plurality of first fins; and
a second heat sink, having a plurality of second fins;
wherein the first and the second heat sinks are disposed adjacently, and the arrangement of the first and the second fins is different.

2. The composite heat dissipating structure according to claim 1, wherein the amount of the first fins is different from that of the second fins.

3. The composite heat dissipating structure according to claim 2, wherein the first and the second fins are arranged in horizontal distribution, vertical distribution, inclined distribution, radial distribution or any other distribution.

4. The composite heat dissipating structure according to claim 1, wherein the first heat sink has a first heat conductive part to which the first fins are connected, and the second heat sink has a second heat conductive part to which the second fins are connected.

5. The composite heat dissipating structure according to claim 4, wherein the first heat conductive part has an indentation coupling to a protrusion of the second heat conductive part so that the first and the second heat sinks are disposed adjacently.

6. The composite heat dissipating structure according to claim 4, wherein the connection between the first and the second heat conductive parts is selected from the group consisting of welding, embedding, locking and adhesion.

7. The composite heat dissipating structure according to claim 6, further comprising a soldering paste, a grease or a material for thermal interface disposed between the first and the second heat conductive parts.

8. The composite heat dissipating structure according to claim 4, wherein the first and the second heat conductive parts are embedded and/or locked by thermal mounting.

9. The composite heat dissipating structure according to claim 4, wherein the first and the second heat conductive parts have a through hole respectively and the through holes are connected for accommodating a corresponding heat conducting base so that the first and the second heat sinks are disposed adjacently.

10. The composite heat dissipating structure according to claim 9, wherein the heat conducting base is a solid metal or a thermal pipe which is made of plastic, metal, alloy or nonmetal.

11. The composite heat dissipating structure according to claim 1, further comprising a third heat sink having a plurality of third fins, the third heat sink is disposed adjacently to the second heat sink, and the arrangement of the third and the second fins is different.

12. The composite heat dissipating structure according to claim 11, wherein the third fins are arranged in horizontal distribution, vertical distribution, inclined distribution, radial distribution or any other distribution.

13. The composite heat dissipating structure according to claim 11, wherein the third heat sink is made by an extruded aluminum molding.

14. The composite heat dissipating structure according to claim 1, wherein the first and/or the second heat sinks are made by an extruded aluminum molding.

15. A heat dissipating assembly, comprising:
a composite heat dissipating structure, comprising;
a first heat sink, having a plurality of first fins; and
a second heat sink, having a plurality of second fins, wherein the first and the second heat sinks are disposed adjacently, and the arrangement of the first and the second fins is different; and
a fan, applied to the composite heat dissipating structure for dissipating heat accumulated in the composite heat dissipating structure.

16. The heat dissipating assembly according to claim 15, wherein the amount of the first fins is different from that of the second fins.

17. The heat dissipating assembly according to claim 15, wherein the first heat sink has a first heat conductive part to which the first fins are connected, and the second heat sink has a second heat conductive part to which the second fins are connected.

18. The heat dissipating assembly according to claim 17, wherein the first and the second heat conductive parts have a through hole respectively and the through holes are connected for accommodating a corresponding heat conducting base so that the first and the second heat sinks are disposed adjacently.

19. The heat dissipating assembly according to claim 15, wherein the heat dissipating assembly is applied to a heat source, the first heat sink is close to the heat source while the second heat sink is apart from the heat source, and the amount of the first fins is greater than that of the second fins.

20. The heat dissipating assembly according to claim 15, further comprising a locking frame and a support for supporting the composite heat dissipating structure, the composite heat dissipating structure is disposed between the locking frame and the support, and the fan is disposed on the locking frame and is connected to the composite heat dissipating structure by the locking frame.
